(19) United States
(12) Patent Application Publication
(10) Pub. No.: US 2025/0030399 A1
(43) Pub. Date: Jan. 23, 2025

(54) ACOUSTIC RESONATOR FILTER WITH HIGH THERMAL CONDUCTIVITY

(71) Applicant: Murata Manufacturing Co., Ltd., Nagaokakyo-shi (JP)

(72) Inventors: Bryant GARCIA, Mississauga (CA); Bryan KIMBRELL, Goleta, CA (US); John P. KOULAKIS, Los Angeles, CA (US); Greg DYER, Santa Barbara, CA (US); Patrick TURNER, Portola Valley, CA (US)

(21) Appl. No.: 18/773,084

(22) Filed: Jul. 15, 2024

Related U.S. Application Data
(60) Provisional application No. 63/514,463, filed on Jul. 19, 2023.

(51) Int. Cl. H03H 9/08; H03H 3/02; H03H 9/02; H03H 9/10; H03H 9/17; H03H 9/56

(52) U.S. Cl. CPC H03H 9/08; H03H 3/02; H03H 9/02228; H03H 9/105; H03H 9/173; H03H 9/564; H03H 9/568; H03H 2003/021

(57) ABSTRACT

A device may include a substrate that includes a base and an intermediate layer. A device may include a piezoelectric layer supported by the substrate except for a portion of the piezoelectric layer forming a diaphragm that spans a helium filled cavity that extends at least partially in the intermediate layer. A device may include an interdigital transducer (IDT) at a surface of the piezoelectric layer and having interleaved fingers on the diaphragm that have a thickness that is less than 0.5 times a thickness of the diaphragm and greater than 0.2 times the thickness of the diaphragm, wherein one of the base and the intermediate layer of the substrate defines a bottom surface of the helium filled cavity that faces the diaphragm such that a cavity depth is between 1.0 μm to 6.0 μm.

### CROSS REFERENCE TO RELATED APPLICATIONS

This present application claims priority to U.S. Patent Provisional Application No. 63/514,463, filed Jul. 19, 2023, the entire contents of which are hereby incorporated by reference.

### TECHNICAL FIELD

This disclosure relates to radio frequency filters using acoustic wave resonators, and specifically to acoustic wave resonators and filters for use in communications equipment and having improved thermal conductivity.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHz. However, it is desired to provide improved heat dissipation and transfer during operation of XBARs to further improve the overall RF filter performance.

### SUMMARY

Thus, according to an exemplary aspect, an acoustic resonator is provided that includes a substrate; an intermediate layer disposed on the substrate and having a gas filled cavity that extends at least partially therein, the gas filled cavity having a heat dissipation gas having a thermal transport property greater than air; a piezoelectric layer having a portion that forms a diaphragm that is over the gas filled cavity; and an interdigital transducer (IDT) on a surface of the piezoelectric layer and having interleaved fingers on the diaphragm that have a thickness that is less than 0.5 times a thickness of the piezoelectric layer and greater than 0.2 times the thickness of the piezoelectric layer. According to the exemplary aspect, a bottom surface of the gas filled cavity faces the diaphragm and a cavity depth between the bottom surface and the piezoelectric layer is between 1.0 μm to 6.0 μm. Moreover, the respective thicknesses and the cavity depth are measured in a direction substantially orthogonal to the surface of the piezoelectric layer.

In another exemplary aspect, one of the substrate and the intermediate layer defines the bottom surface of the gas filled cavity.

In another exemplary aspect, the heat dissipation gas is helium.

In another exemplary aspect, the intermediate layer comprises silicon oxide or silicon dioxide.

In another exemplary aspect, a top surface of the substrate defines the bottom surface of the gas filled cavity, the intermediate layer defines a sidewall of the gas filled cavity, and a diffusion barrier is disposed on the sidewall of the gas filled cavity.

In another exemplary aspect, a top surface of the substrate defines the bottom surface of the gas filled cavity, the intermediate layer defines a sidewall of the gas filled cavity, and a bonding material defines an exterior wall of the gas filled cavity. Moreover, the bonding material can be a plurality of metal layers.

In another exemplary aspect, the surface of the piezoelectric layer is coupled to a package forming an additional gas filled cavity, and the piezoelectric layer includes holes through which the heat dissipation gas disperses between the gas filled cavity and the additional gas filled cavity. Moreover, the package can include a silicon lid defining a top of the additional gas filled cavity, and a bonding material defining an exterior wall of the additional gas filled cavity.

In another exemplary aspect, the IDT is configured such that a radio frequency signal applied to the IDT excites a bulk shear acoustic wave in the diaphragm where acoustic energy propagates along a direction substantially orthogonal to a surface of the piezoelectric layer, which is transverse to a direction of an electric field created by the interleaved fingers of the IDT.

In yet another exemplary aspect, a filter device is provided that includes a plurality of bulk acoustic resonators. In this aspect, at least one bulk acoustic resonator comprises a substrate; an intermediate layer disposed on the substrate and having a gas filled cavity that extends at least partially therein, the gas filled cavity having a heat dissipation gas having a thermal transport property greater than air; a piezoelectric layer having a portion that forms a diaphragm that is over the gas filled cavity; and an interdigital transducer (IDT) on a surface of the piezoelectric layer and having interleaved fingers on the diaphragm that have a thickness that is less than 0.5 times a thickness of the piezoelectric layer and greater than 0.2 times the thickness of the piezoelectric layer. Moreover, a bottom surface of the gas filled cavity faces the diaphragm and a cavity depth between the bottom surface and the piezoelectric layer is between 1.0 μm to 6.0 μm. Furthermore, the respective thicknesses and the cavity depth are measured in a direction substantially orthogonal to the surface of the piezoelectric layer.

In yet another exemplary aspect, a radio frequency module is provided that includes a filter device including a plurality bulk acoustic resonators connected in parallel; and a radio frequency circuit coupled to the filter device, the filter device and the radio frequency circuit being enclosed within a common package. In this aspect, at least one of the plurality of bulk acoustic resonators of the filter device includes a substrate; an intermediate layer disposed on the substrate and having a gas filled cavity that extends at least partially therein, the gas filled cavity having a heat dissipation gas having a thermal transport property greater than air; a piezoelectric layer having a portion that forms a diaphragm that is over the gas filled cavity; and an interdigital transducer (IDT) on a surface of the piezoelectric layer and having interleaved fingers on the diaphragm that have a thickness that is less than 0.5 times a thickness of the piezoelectric layer and greater than 0.2 times the thickness of the piezoelectric layer. Moreover, in this aspect, a bottom surface of the gas filled cavity faces the diaphragm and a cavity depth between the bottom surface and the piezoelectric layer is between 1.0 μm to 6.0 μm. Furthermore, the respective thicknesses and the cavity depth are measured in a direction substantially orthogonal to the surface of the piezoelectric layer.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 3A is a schematic cross-sectional view of an XBAR according to an exemplary aspect.

FIG. 3B is another alternative schematic cross-sectional view of an XBAR according to an exemplary aspect.

FIG. 3C is another alternative schematic cross-sectional view of an XBAR according to an exemplary aspect.

FIG. 3D is another alternative schematic cross-sectional view of an XBAR according to an exemplary aspect.

FIG. 3E is another alternative schematic cross-sectional view of an XBAR according to an exemplary aspect.

FIG. 3F is a top plan view of an XBAR according to an exemplary aspect.

FIG. 3G is another top plan view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 shows a graph illustrating the thermal resistance versus FSE cavity depth with respect to gases species.

FIG. 7 shows a graph illustrating the impact of gas species and cavity depth on thermal transport with respect to gases species.

FIG. 8 illustrates a flowchart of a method of manufacturing a filter as described herein according to an exemplary aspect.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

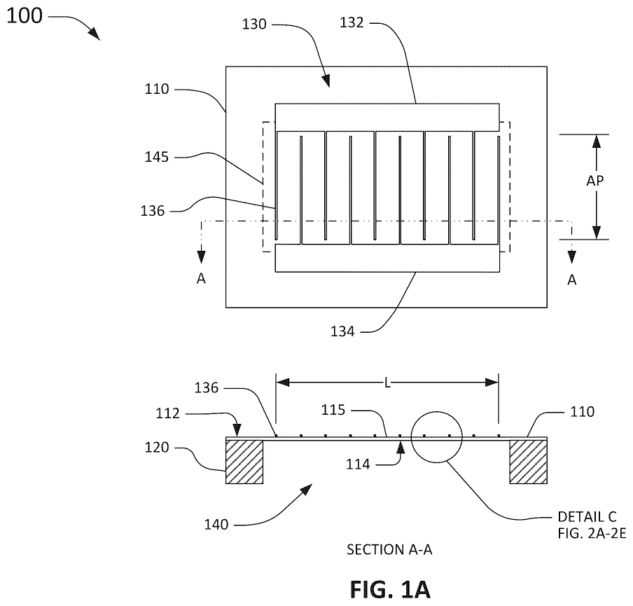

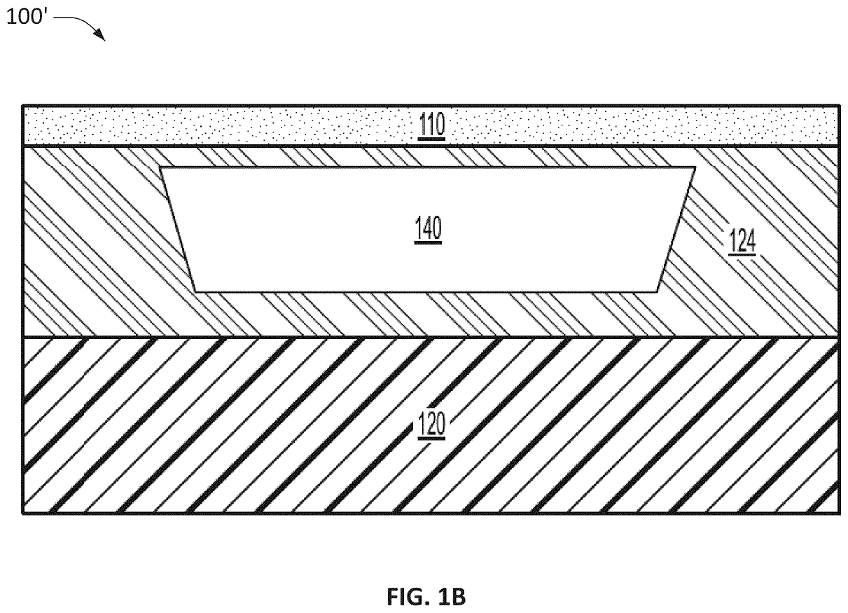

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0° ] is commonly referred to as “120° rotated Y-cut” or “120Y.” Thus, the Euler angles for 120YX and 128YX are (0, 120−90, 0) and (0, 128−90, 0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

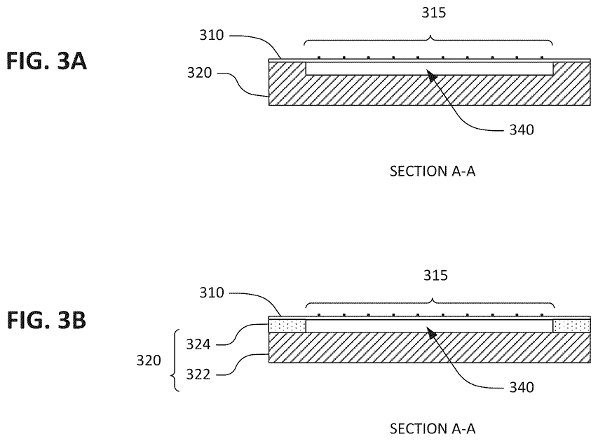

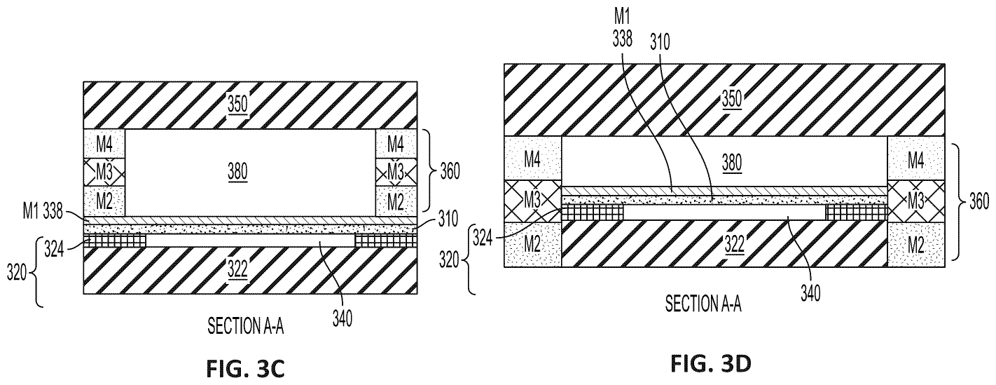

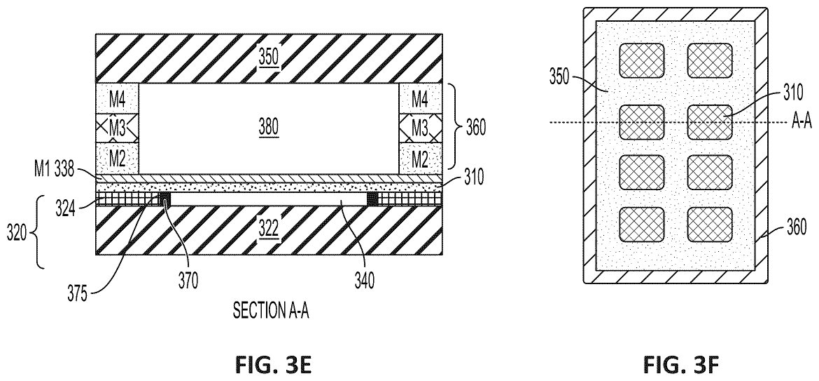

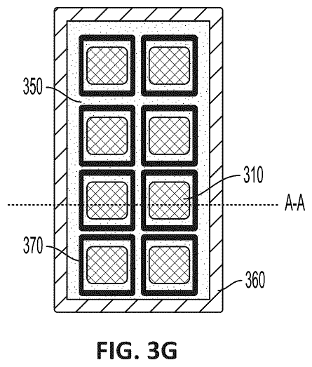

For purposes of this disclosure, “cavity” has its conventional meaning of “an empty space within a solid body.” The cavity 140 may be a hole completely through the substrate 120 (as shown in Section A-A and Section B-B) or a recess in the substrate 120 (as shown subsequently in FIG. 3A, FIG. 3B, FIG. 3C, FIG. 3D and FIG. 3E). The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the examples of FIGS. 1A-1B, FIG. 3A., FIG. 3B, FIG. 3C, FIG. 3D and FIG. 3E the IDT 130 is on the front surface 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

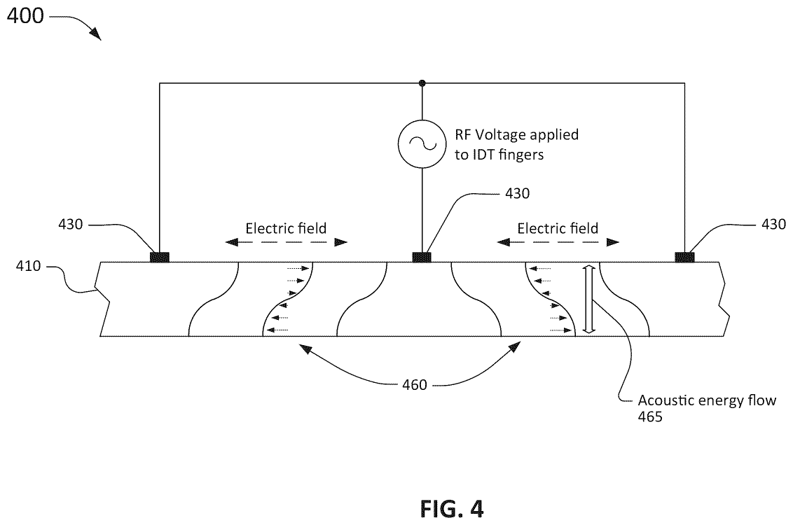

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

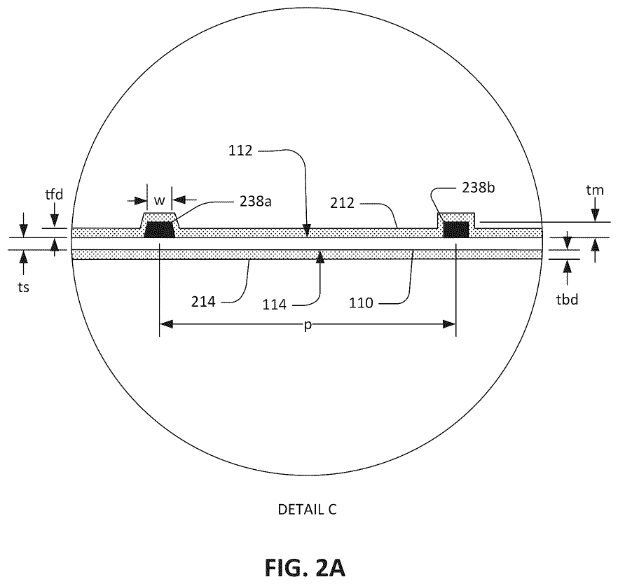

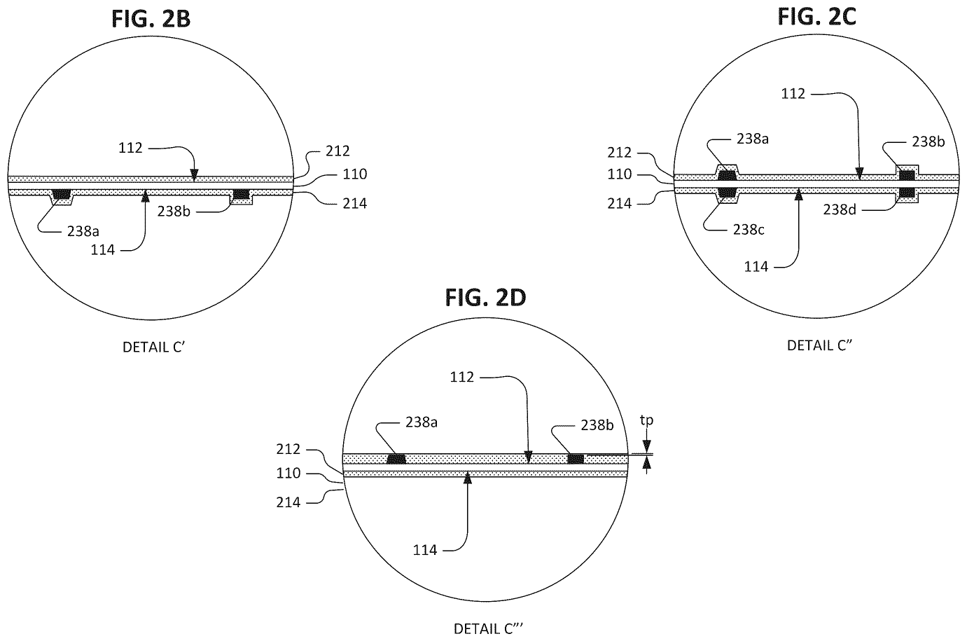

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nm to 1500 nm. When used in filters for 5G NR and Wi-Fi™ bands from 3.4 GHZ to 7 GHz, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

FIG. 3A, FIG. 3B, FIG. 3C, FIG. 3D and FIG. 3E illustrate five alternative cross-sectional views along the section plane A-A defined in FIG. 1A. FIG. 3F and FIG. 3G illustrate alternative top plan views of FIG. 3D and FIG. 3E, respectively.

As shown in FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 3C, FIG. 3D and FIG. 3E illustrate alternative aspects in which the substrate 320 includes a base 322 and an intermediate layer 324 that is disposed between the piezoelectric layer 310 and the base 322. For example, the base 322 may be silicon and the intermediate layer 324 may be silicon oxide, silicon dioxide or silicon nitride or some other material, e.g., an intermediate dielectric layer. That is, in this aspect, the base 322 and the intermediate layer 324 are collectively considered the substrate 320, but it should be appreciated that the base 322 can be considered a substrate and the intermediate layer can be one or more intermediate (e.g., dielectric layers) disposed thereon. As further shown, cavity 340 is formed in the intermediate layer 324 under the portion of the piezoelectric layer 310 having the interleaved IDT fingers of an XBAR disposed thereon. As shown in FIG. 3C, the cavity 340 extends completely through the intermediate layer 324 to a top surface of the base 322 of the substrate 320. Thus, one of the base 322 of the substrate 320 and the intermediate layer 324 defines the bottom surface of the gas filled cavity 340. In this aspect, the piezoelectric layer 310 can have a portion over the cavity 340 that forms a diaphragm with at least 50% of the edge surface of the diaphragm coupled to the edge (e.g., perimeter) of the dielectric layer(s) 324 facing the piezoelectric layer 310.

In general, XBAR resonators based on free-standing membranes as described above in reference to FIG. 3A and FIG. 3B often have a large thermal impedance for heat dissipated during high power operation. This limits operating power and product lifetime. In one aspect of the disclosure, the cavity 340 may be hermetic packaged, for example, as a frontside etch (FSE) cavity filled with a gas provided for heat dissipation (e.g., a “heat dissipation gas”), such as helium (He), neon (Ne) or other high thermal conductivity gas that has a higher thermal transport property than air, in order to provide an environment that increases thermal conduction from the piezoelectric layer 310 to substrate 320.

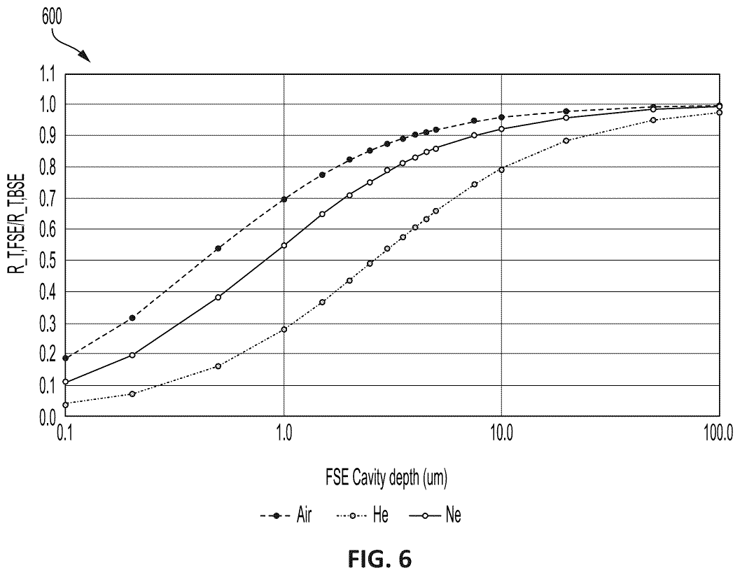

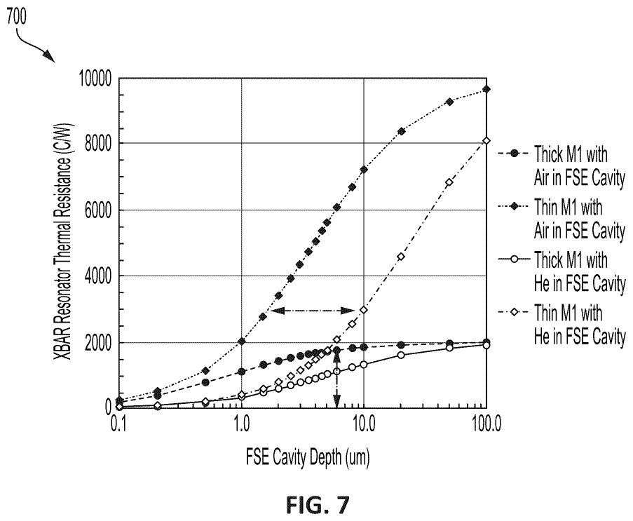

As described with reference to FIG. 3C, FIG. 3D and FIG. 3E, there are two primary heat conduction channels for XBAR resonators: lateral conduction on the membrane, primarily in the electrodes, and vertical conduction through cavity 340 between the piezoelectric layer 310 to substrate 320. To improve the former path, narrowing of the resonator aperture may be used, but this tends to degrade the acoustic Q factor. To improve the latter, the cavity 340 may be shallower (i.e., closer to the diaphragm), but this configuration reduces effective acoustic coupling and risks incomplete release of the membrane from the substrate. Thus, according to an exemplary aspect, a higher thermal conductivity gas (i.e., a heat dissipation gas), such as helium, is utilized to provide for aperture and cavity dimensions to remain optimal, while improving heat sinking and dissipation. As illustrated in FIG. 6 and FIG. 7, described below, in one aspect of the disclose the cavity 340 depth (i.e., in the vertical direction between top and bottom surfaces of cavity 340) is between 1.0 μm to 6.0 μm to provide for optimal thermal transport from the IDT during excitation.

The hermetically sealed XBAR filter as described with reference to FIG. 3C, FIG. 3D and FIG. 3E can include a substrate 320, a lid 350 and bonding materials 360, provided these elements are hermetic in enclosing the heat dissipating (e.g., helium) gas, as described above. For example, the XBAR (i.e., the bulk acoustic resonator) can include a substrate 320 and an intermediate layer 324 that can either be considered part of the substrate or disposed on a base 322 of the substrate 320. The intermediate layer 324 can have a gas filled cavity 340 that extends at least partially therein and has a heat dissipation gas having a thermal transport property greater than air. Moreover, the XBAR includes a piezoelectric layer 310 that has a portion that forms a diaphragm that is over the gas filled cavity 340. A metal layer 338 (e.g., M1) includes an interdigital transducer (IDT) on a surface of the piezoelectric layer 310 and has interleaved fingers on the diaphragm that have preferably a thickness that is less than 0.5 times a thickness of the piezoelectric layer 310 and greater than 0.2 times the thickness of the piezoelectric layer 310. Moreover, as described herein, a bottom surface of the gas filled cavity 340 faces the diaphragm and has a cavity depth that is between the bottom surface and the piezoelectric layer 310 and is between 1.0 μm to 6.0 μm. As also described herein, the respective thicknesses and the cavity depth are measured in a direction substantially orthogonal to the surface of the piezoelectric layer 310. In this and similar contexts for purposes of this disclosure, the term “respective” means “relating things each to each”, which is to say with a one-to-one correspondence. For example, the respective thicknesses here mean the thickness of both the piezoelectric layer 310 and interleaved fingers are measured in a direction substantially orthogonal to the surface of the piezoelectric layer 310.

In an exemplary aspect, the lid 350 can be a same material as the base 322 of the substrate, such as silicon, sapphire, quartz, or some other material or combination of materials. Moreover, the bonding materials 360 may comprise metal layers, for example, gold (Au), or other known materials to generate a thermocompression bond. Although four metal layers are illustrated, any number of metal layers may be implemented to achieve a hermetic seal. The cavity 340 can be considered a gas filled cavity when filled with the heat dissipating gas, such as helium. Thus, in this aspect, the package includes a lid 350 (e.g., a silicon lid) that defines a top of the additional gas filled cavity 380, and a bonding material 360 of one or more metal layers defines an exterior wall of the additional gas filled cavity 380.

According to the exemplary embodiments shown in FIG. 3D and FIG. 3F, the bonding materials 360 (e.g., metal layers M2, M3, and M4) are disposed outside the diaphragm of the piezoelectric layer 310 (i.e., relative to the cavity), the interleaved fingers 338 (e.g., metal layer M1) and the substrate 320. That is, a top surface of the base 322 (e.g., silicon substrate) defines the bottom surface of the gas filled cavity 340, the intermediate layer 324 (e.g., a dielectric layer(s)) defines a sidewall of the gas filled cavity 340, and a bonding material (e.g., one or more of metal layers of the bonding materials 360) defines an single exterior wall of all of the gas filled cavities. This configuration provides additional containment and/or hermetically sealing of the gas filled within the gas filled cavity 340. It should be appreciated that FIG. 3F illustrates a filter device comprising a plurality of bulk acoustic resonators (e.g., denoted by and having a piezoelectric layer 310 with the lid 350 disposed thereon. The bonding materials 360 encapsulate (e.g., surround) a plurality of bulk acoustic resonators (e.g., some or all devices) of the filter device to hermetically seal the cavity as described herein.

As described with reference to FIG. 3C, FIG. 3D and FIG. 3E, the gas contained with the gas filled cavity 340 may be contained and/or sealed via an intermediate layer 324, where the intermediate layer 324 may be SiO2 for example. However, intermediate layer 324 may not provide for a complete hermetic seal thereby completely containing the gas within the gas filled cavity 340, as the gas may interact with the dielectric layer(s) and diffuse out of the gas filled cavity 340. As illustrated in FIG. 3D, to provide for a complete extra seal and/or containment of the gas within the gas filled cavity 340, the intermediate layer 324 may be surrounded and/or encapsulated by the bonding materials 360 (e.g., a “barrier” or “cavity barrier”). The bonding materials 360 may comprise one or more of metal layers M1, M2 and M3. It is reiterated that although three metal layers of the bonding materials 360 are illustrated, any number metal layers may be implemented with any size (thickness and/or width) to surround and/or encapsulate the intermediate layer 324 and the gas filled cavity 340. This structure allows for a rigorous seal of the gas contained with the gas filled cavity 340. By containing the gas within gas filled cavity 340, gas will not diffuse over time/use and, thus, the heat dissipation and thermal transport can be maintained over use and life of the resonator.

It is noted that metal layer 338 (e.g., metal layer M1) of each of FIGS. 3C to 3E can correspond to any of interleaved fingers 238a, 238b described above. Thus, while metal layer 338 is shown to be on a top surface of the diaphragm of piezoelectric layer 310 in FIGS. 3C, 3D and 3E, in alternative aspects, the metal layer 338 can be on the bottom surface facing the gas filled cavity 340 and/or both surfaces as also described above.

In another aspect of the disclosure, with reference to FIG. 3E and FIG. 3G, the intermediate layer 324, being an intermediate dielectric layer, may also include a diffusion barrier 370 comprising gold (Au) or other denser metals compared to aluminum (Al). This configuration may provide for additional containment and/or hermetically sealing of the gas filled within the gas filled cavity 340 and address the potential sealing failures as described above (e.g., the gas diffusing into the dielectric layer(s)). Accordingly, in this aspect, a top surface of the base 322 defines the bottom surface of the gas filled cavity 340, the intermediate layer 324 defines a sidewall 375 of the gas filled cavity, and a diffusion barrier 370 is disposed on the sidewall 375 of the gas filled cavity 340 to prevent the heat dissipation gas, such as helium, from diffusing into the SiO2 material of the intermediate layer 324. In general, oxide layers (e.g., silicon oxide and dioxide) are porous and helium can diffuse therein. Thus, in the exemplary aspect, the diffusion barrier 370 is a material with such properties in which the heat dissipation gas (e.g., helium) can diffuse or pass therethrough. For example, the diffusion barrier 370 can be a metal or metallic material but can also be a single crystalline material that is configured as a barrier for the heat dissipation gas in the cavity. It should be appreciated that FIG. 3G illustrates that a diffusion barrier 370 is provided to surround (and hermetically seal) the cavity for each bulk acoustic resonator having a respective piezoelectric layer 310. Moreover, the bonding materials 360 surrounding the entirety of the filter device in a similar configuration as described herein with respect to FIG. 3F.

Moreover, in one aspect of the disclosure, the piezoelectric layer 310 may have holes or perforations that allow for the heat dissipation gas (e.g., helium gas) in the packaging environment/hermetic top cavity 380 to fill (e.g., disperse) the gas filled cavity 340 and vice versa. Moreover, electrical routing may pass through the lid 350 with through silicon vias (e.g., TSVs), not illustrated. As described below with reference to FIG. 6 and FIG. 7, the heat dissipation gas (e.g., helium gas) gas has a six times higher thermal conductivity than air, and thus the gas filled cavity 340 depth may be increased by six times when a heat dissipation gas is provided within the gas filled cavity 340 when compared to a cavity filled with air to achieve the same thermal dissipation performance.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D and 3A to 3E according to an exemplary aspect. Thus, it should be appreciated that piezoelectric layer 410 can correspond to piezoelectric layer 110 and/or 310 and IDT fingers 430 can be implemented according to any of the configurations of fingers 238a and 238b and/or 338, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

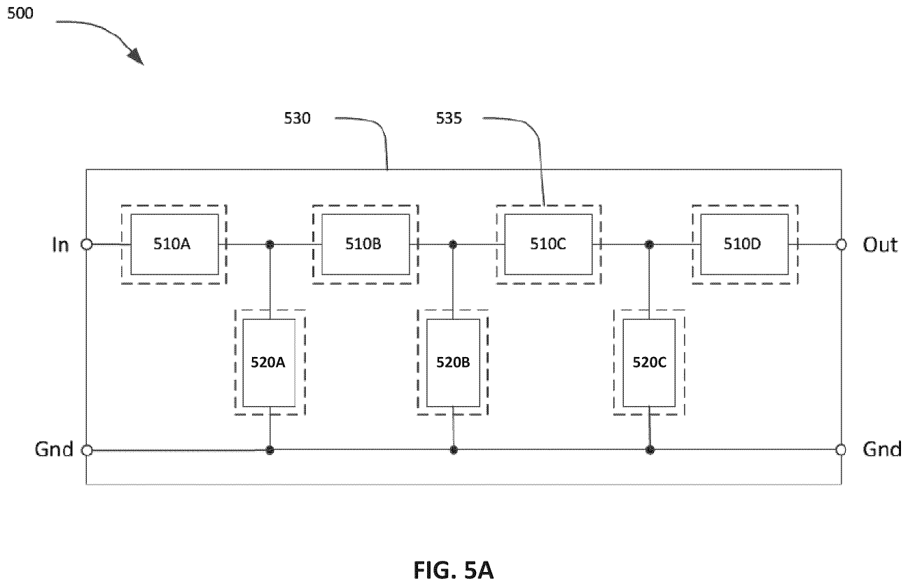

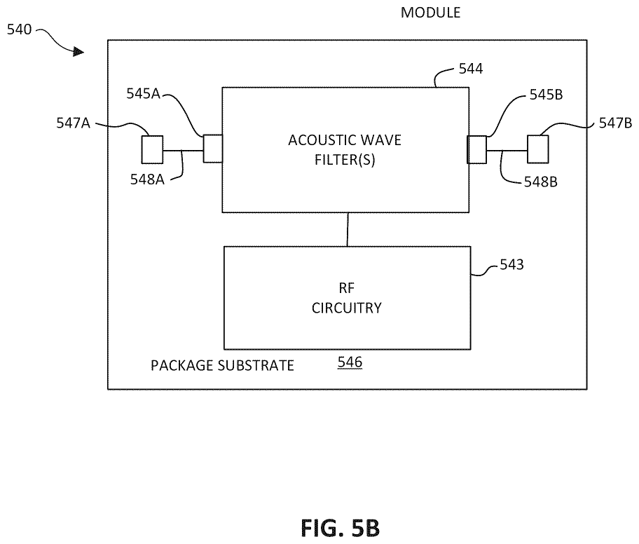

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500. According to an exemplary aspect, at least one and/or each of the series resonators 510A, 510B, 510C and 510D and the shunt resonators 520A, 520B and 520C can have an XBAR configuration as described above with respect to FIGS. 1A-2D and 3A-3E in which a diaphragm with IDT fingers spans over a cavity. Moreover, one, some or all of the bulk acoustic resonators pf the filter circuit 500 can be included in a package structure such as that described in FIGS. 3E and/or 3F as described above.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (a radio frequency circuit or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

As described above, in exemplary aspects, an XBAR configuration is provided in which cavity between the piezoelectric layer and the substrate (e.g., in a portion or all of the intermediate dielectric layer) has a cavity depth (i.e., in the vertical direction between top and bottom surfaces of cavity 340) that is between 1.0 μm to 6.0 μm to provide for optimal thermal transport from the IDT during excitation. In this regard, FIG. 6 shows a graph 600 illustrating the thermal resistance versus cavity depth with respect to gases species. The data for FIG. 6 and all subsequent graphs results from simulation of exemplary XBAR devices using a finite element three-dimensional simulation technique. As shown, the positive thermal resistance diminishes as the depth of the cavity increases. Providing either neon (Ne) or helium (He) gas in the cavity enables a 30% reduction in thermal resistance relative to back side etch (BSE) cavity for approximately 2.0 and 6.0 μm FSE cavity depths, respectively, in comparison to 1.0 μm cavity depth with air. For a 1.0 μm FSE cavity depth, Ne and He enable respective thermal resistance reductions of 45% and 72%, respectively, compared to BSE. According to one aspect of the disclosure, the effective range of usable cavity depths may be estimated from 0.1 um to 10 um, depending on the fill gas and acceptable parasitic capacitance. More specifically, the FSE cavity depth is most beneficial by providing the highest levels of improved thermal transport when the cavity depth is between 1.0 μm and 6.0 μm when filled with helium (He) as the heat dissipation gas. As a result, heat generated by the IDT during operation of the XBAR is significantly improved by providing such a cavity depth filled with helium (He) as the heat dissipation gas.

As described above, the deeper the gas filled cavity 340 is formed, the less of a positive effect the gas contained within the cavity provides for thermal transport. For example, as illustrated in FIG. 6, once the cavity reaches a cavity depth of greater than 10 μm, the performance of the heat dissipation gas within the FSE cavity becomes the same or provides for a nominal improvement compared with an oxygen filled cavity. This is because the cavity depth itself provides for the thermal transport, for example, spacing between the physical materials of the resonator. Moreover, when the cavity has a depth of 1 μm to 6 μm, the heat dissipation gas provides the thermal transport to remove heat from the IDT of the XBAR during excitation and operation. Although even smaller depths of the cavity also provide for improved thermal transport, for example, 0.1 μm to 1.0 μm, physical constraints of manufacturing processes inhibit the actual production of an XBAR with heat dissipation gas filled cavities within those specifications. In addition, a very small cavity depth may result in the diaphragm contacting the top of the cavity during operation.

FIG. 7 shows a graph 700 that illustrates an impact of gas species and cavity depth on XBAR thermal transport with respect to different gases and different layers M1, which is an IDT layer including the IDT fingers 238a and 238b as described above in FIG. 2A to FIG. 2D and metal layer 338 of FIGS. 3A to 3E, for example. As illustrated in FIG. 7, a cavity depth of approximately 10 μm for a ‘thin’ M1 with He gas within the FSE cavity achieves the same performance as air within the FSE cavity at a depth of 1.5 um. However, a ‘thin’ M1 for an air-filled cavity at approximately 10 μm depth has a significantly higher thermal resistance (˜7000 C/W) compared with the same helium filled cavity (˜3000 C/W). Moreover, as further illustrated in FIG. 7, a cavity depth of approximately 6 μm for a ‘thin’ M1 with He gas within the FSE achieves the same performance as air within the FSE cavity with a ‘thick” M1. Accordingly, the thermal transport is significantly greater for helium filled cavities with resonators having thin metal (e.g., 0.08 μm) compared with thicker metal (e.g., 0.4 μm). Thus, in an exemplary aspect, the IDT has interleaved fingers on the diaphragm that have a thickness (i.e., in the thickness direction normal or orthogonal to a surface of the diaphragm/piezoelectric layer) that is less than 0.5 times a thickness of the piezoelectric layer (e.g., the diaphragm) and greater than 0.2 times the thickness of the piezoelectric layer (e.g., the diaphragm). The improved thermal transport property of a helium filled cavity are significantly improved for such “thin” metal XBAR devices compared with thick metal IDTs.

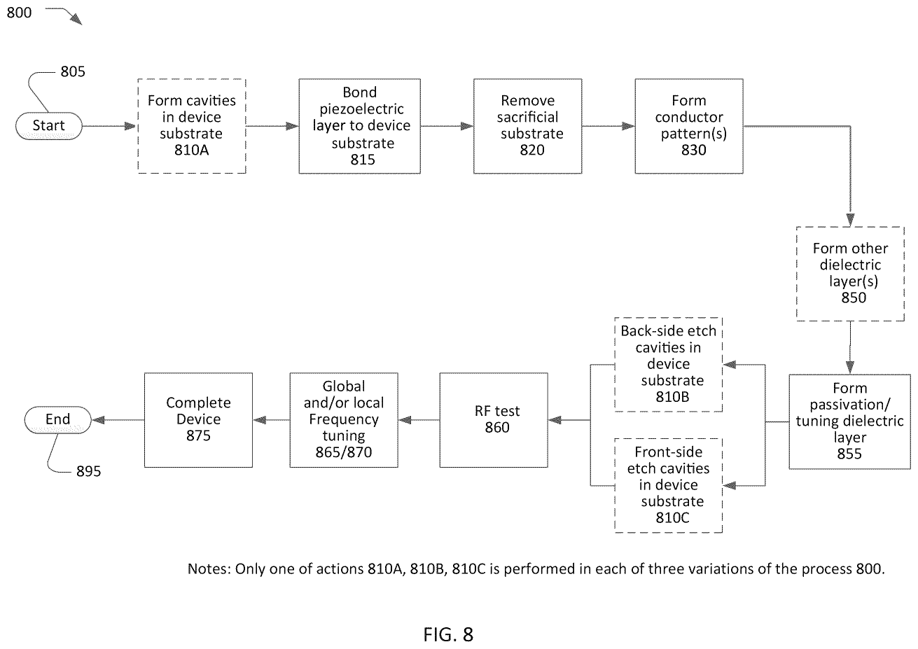

FIG. 8 illustrates a flowchart of a method of manufacturing a filter as described herein according to an exemplary aspect. In particular, method 800 summarizes an exemplary manufacturing processing for fabricating a filter device incorporating XBARs as described herein. Specifically, the process 800 is for fabricating a filter device including multiple XBARs, including extracted pole resonators. The process 800 starts at 805 with a device substrate and a thin layer of piezoelectric material disposed on a sacrificial substrate. The process 800 ends at 895 with a completed filter device. The flow chart of FIG. 8 includes only major process steps. Various conventional process steps (e.g., surface preparation, cleaning, inspection, baking, annealing, monitoring, testing, etc.) may be performed before, between, after, and during the steps shown in FIG. 8.

While FIG. 8 generally describes a process for fabricating a single filter device, multiple filter devices may be fabricated simultaneously on a common wafer (including a piezoelectric layer bonded to a substrate). In this case, each step of the process 800 may be performed concurrently on all of the filter devices on the wafer.

The flow chart of FIG. 8 captures three variations of the process 800 for making an XBAR which differ in when and how cavities are formed in the device substrate. The cavities may be formed at steps 810A, 810B, or 810C. Only one of these steps is performed in each of the three variations of the process 800. As described herein, the cavity can be formed by each of these exemplary steps to have a cavity depth that is between the bottom surface and the piezoelectric layer and that is between 1.0 μm to 6.0 μm. as also described herein, the respective thicknesses and the cavity depth are measured in a direction substantially orthogonal to the surface of the piezoelectric layer.

In an exemplary aspect, the piezoelectric layer may typically be Z-cut or 82Y-cut lithium niobate. The piezoelectric layer may be some other material and/or some other cut. The device substrate may preferably be silicon. The device substrate may be some other material that allows formation of deep cavities by etching or other processing.

In one variation of the process 800, one or more cavities are formed in the device substrate at 810A, before the at least one piezoelectric layer is bonded to the substrate at 815. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities may be formed using conventional photolithographic and etching techniques. Typically, the cavities formed at 810A will not penetrate through the device substrate.

At 815, the at least one piezoelectric layer is bonded to the device substrate. The at least one piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. One or both mating surfaces may be activated using, for example, a plasma process. The mating surfaces may then be pressed together with considerable force to establish molecular bonds between the piezoelectric layer and the device substrate or intermediate material layers.

At 820, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 820, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

A first conductor pattern (e.g., metal layer M1), including IDTs of each XBAR, is formed at 830 by depositing and patterning one or more conductor layers on the front side of the piezoelectric layer. The conductor layer may be, for example, aluminum, an aluminum alloy, copper, a copper alloy, or some other conductive metal. In some aspects, one or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Each conductor pattern may be formed at 830 by depositing the conductor layer and, in some aspects, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 830 using a lift-off process. Photoresist may be deposited over the piezoelectric layer and patterned to define the conductor pattern. The conductor layer and, in some aspects, one or more other layers may be deposited in sequence over the surface of the piezoelectric layer. The photoresist may then be removed, which removes the excess material, leaving the conductor pattern.

As described above, the resonant frequencies of each acoustic resonator may be set according to the pitch of each IDT in one aspect. Thus, at 830, the pitch of the high side extracted pole resonator may be set to be smaller than the pitches of series resonators 510A to 510C, for example, such that they have a higher frequency. Moreover, the pitch of the low side extracted pole resonator may be set to be larger than the pitches of shunt resonators 520B to 520B, for example, such that they have a lower frequency.

At 855, a passivation/tuning dielectric layer may be deposited over the piezoelectric layer and conductor patterns. The passivation/tuning dielectric layer may cover the entire surface of the filter except for pads for electrical connections to circuitry external to the filter. In some instantiations of the process 800, the passivation/tuning dielectric layer may be formed after the cavities in the device substrate are etched at either 810B or 810C.

In a second variation of the process 800, one or more cavities are formed in the back side of the device substrate at 810B. The one or more cavities may comprise a depth between 1.0 μm and 6.0 μm and can be filled with helium, for example. A separate cavity may be formed for each resonator in a filter device. Also, the cavities can be shaped and formed such that plurality of resonators can be on one diaphragm over one cavity. These resonators sharing a diaphragm are acoustically coupled on an acoustic track. The one or more cavities may be formed using an anisotropic or orientation-dependent dry or wet etch to open holes through the back side of the device substrate to the piezoelectric layer. In this case, the resulting resonator devices will have a cross-section as shown and described in the exemplary aspects of FIGS. 3A to 3E, for example.

In a third variation of the process 800, one or more cavities in the form of recesses in the device substrate may be formed at 810C by etching the substrate using an etchant introduced through openings in the piezoelectric layer. The one or more cavities may comprise a depth between 1.0 μm and 6.0 μm and can be filled with helium, for example. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities formed at 810C will not penetrate through the device substrate.

Ideally, after the cavities are formed at 810B or 810C, most or all of the filter devices on a wafer will meet a set of performance requirements. However, normal process tolerances will result in variations in parameters such as the thicknesses of dielectric layers formed at 850 and 855, variations in the thickness and line widths of conductors and IDT fingers formed at 830, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 855. The frequency of a filter device passband can be lowered by adding material to the passivation/tuning layer, and the frequency of the filter device passband can be increased by removing material from the passivation/tuning layer. Typically, the process 800 is biased to produce filter devices with passbands that are initially lower than a required frequency range but can be tuned to the desired frequency range by removing material from the surface of the passivation/tuning layer.

At 860, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 865, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 860 may be processed to generate a global contour map indicating the amount of material to be removed as a function of two-dimensional position on the wafer. The material is then removed in accordance with the contour map using the selective material removal tool.

At 870, local frequency tuning may be performed in addition to, or instead of, the global frequency tuning performed at 865. “Local” frequency tuning is performed with a spatial resolution smaller than an individual filter device. The test results from 860 may be processed to generate a map indicating the amount of material to be removed at each filter device. Local frequency tuning may require the use of a mask to restrict the size of the areas from which material is removed. For example, a first mask may be used to restrict tuning to only shunt resonators, a second mask may be subsequently used to restrict tuning to only series resonators, and a third mask may be subsequently used to restrict tuning to only extracted pole resonators. This would allow independent tuning of the lower band edge and upper band edge of the filter devices.

After frequency tuning at 865 and/or 870, the filter device is completed at 875. Actions that may occur at 875 include forming bonding pads or solder bumps or other means for making connection between the device and external circuitry (if such pads were not formed at 830); excising individual filter devices from a wafer containing multiple filter devices; other packaging steps; and additional testing. After each filter device is completed, the process ends at 895.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/of” means that the listed items are alternatives, but the alternatives also include any combination of the listed items.

What is claimed:

1. An acoustic resonator comprising:
a substrate;
an intermediate layer disposed on the substrate and having a gas filled cavity that extends at least partially therein, the gas filled cavity having a heat dissipation gas having a thermal transport property greater than air;
a piezoelectric layer having a portion that forms a diaphragm that is over the gas filled cavity; and
an interdigital transducer (IDT) on a surface of the piezoelectric layer and having interleaved fingers on the diaphragm that have a thickness that is less than 0.5 times a thickness of the piezoelectric layer and greater than 0.2 times the thickness of the piezoelectric layer,
wherein a bottom surface of the gas filled cavity faces the diaphragm and a cavity depth between the bottom surface and the piezoelectric layer is between 1.0 μm to 6.0 μm, and
wherein the respective thicknesses and the cavity depth are measured in a direction substantially orthogonal to the surface of the piezoelectric layer.

2. The acoustic resonator according to claim 1, wherein one of the substrate and the intermediate layer defines the bottom surface of the gas filled cavity.

3. The acoustic resonator according to claim 1, wherein the heat dissipation gas is helium.

4. The acoustic resonator according to claim 1, wherein the intermediate layer comprises silicon oxide or silicon dioxide.

5. The acoustic resonator according to claim 1, wherein a top surface of the substrate defines the bottom surface of the gas filled cavity, the intermediate layer defines a sidewall of the gas filled cavity, and a diffusion barrier is disposed on the sidewall of the gas filled cavity.

6. The acoustic resonator according to claim 1, wherein a top surface of the substrate defines the bottom surface of the gas filled cavity, the intermediate layer defines a sidewall of the gas filled cavity, and a bonding material defines an exterior wall of the gas filled cavity.

7. The acoustic resonator according to claim 6, wherein the bonding material comprises a plurality of metal layers.

8. The acoustic resonator according to claim 1, wherein the surface of the piezoelectric layer is coupled to a package forming an additional gas filled cavity, and the piezoelectric layer includes holes through which the heat dissipation gas disperses between the gas filled cavity and the additional gas filled cavity.

9. The acoustic resonator according to claim 8, wherein the package includes a silicon lid defining a top of the additional gas filled cavity, and a bonding material defining an exterior wall of the additional gas filled cavity.

10. The acoustic resonator according to claim 1, wherein the IDT is configured such that a radio frequency signal applied to the IDT excites a bulk shear acoustic wave in the diaphragm where acoustic energy propagates along a direction substantially orthogonal to a surface of the piezoelectric layer, which is transverse to a direction of an electric field created by the interleaved fingers of the IDT.

11. A filter device comprising:
a plurality of bulk acoustic resonators, wherein at least one bulk acoustic resonator comprises:
a substrate;
an intermediate layer disposed on the substrate and having a gas filled cavity that extends at least partially therein, the gas filled cavity having a heat dissipation gas having a thermal transport property greater than air;
a piezoelectric layer having a portion that forms a diaphragm that is over the gas filled cavity; and
an interdigital transducer (IDT) on a surface of the piezoelectric layer and having interleaved fingers on the diaphragm that have a thickness that is less than 0.5 times a thickness of the piezoelectric layer and greater than 0.2 times the thickness of the piezoelectric layer,
wherein a bottom surface of the gas filled cavity faces the diaphragm and a cavity depth between the bottom surface and the piezoelectric layer is between 1.0 μm to 6.0 μm, and
wherein the respective thicknesses and the cavity depth are measured in a direction substantially orthogonal to the surface of the piezoelectric layer.

12. The filter device according to claim 11, wherein, for the at least one bulk acoustic resonator, one of the substrate and the intermediate layer defines the bottom surface of the gas filled cavity.

13. The filter device according to claim 11, wherein the heat dissipation gas is helium.

14. The filter device according to claim 11, wherein, for the at least one bulk acoustic resonator, a top surface of the substrate defines the bottom surface of the gas filled cavity, the intermediate layer defines a sidewall of the gas filled cavity, and a diffusion barrier is disposed on the sidewall of the gas filled cavity.

15. The filter device according to claim 11, wherein, for the at least one bulk acoustic resonator, a top surface of the substrate defines the bottom surface of the gas filled cavity, the intermediate layer defines a sidewall of the gas filled cavity, and a bonding material defines an exterior wall of the gas filled cavity.

16. The filter device according to claim 15, wherein the bonding material comprises a plurality of metal layers.

17. The filter device according to claim 11, wherein, for the at least one bulk acoustic resonator, the surface of the piezoelectric layer is coupled to a package forming an additional gas filled cavity, and the piezoelectric layer includes holes through which the heat dissipation gas disperses between the gas filled cavity and the additional gas filled cavity.

18. The filter device according to claim 17, wherein the package includes a silicon lid defining a top of the additional gas filled cavity, and a bonding material defining an exterior wall of the additional gas filled cavity.

19. The filter device according to claim 11, wherein, for the at least one bulk acoustic resonator, the IDT is configured such that a radio frequency signal applied to the IDT excites a bulk shear acoustic wave in the diaphragm where acoustic energy propagates along a direction substantially orthogonal to a surface of the piezoelectric layer, which is transverse to a direction of an electric field created by the interleaved fingers of the IDT.

20. A radio frequency module comprising:
a filter device including a plurality bulk acoustic resonators connected in parallel; and
a radio frequency circuit coupled to the filter device, the filter device and the radio frequency circuit being enclosed within a common package, wherein at least one of the plurality of bulk acoustic resonators of the filter device includes:
a substrate;
an intermediate layer disposed on the substrate and having a gas filled cavity that extends at least partially therein, the gas filled cavity having a heat dissipation gas having a thermal transport property greater than air;
a piezoelectric layer having a portion that forms a diaphragm that is over the gas filled cavity; and
an interdigital transducer (IDT) on a surface of the piezoelectric layer and having interleaved fingers on the diaphragm that have a thickness that is less than 0.5 times a thickness of the piezoelectric layer and greater than 0.2 times the thickness of the piezoelectric layer,
wherein a bottom surface of the gas filled cavity faces the diaphragm and a cavity depth between the bottom surface and the piezoelectric layer is between 1.0 μm to 6.0 μm, and
wherein the respective thicknesses and the cavity depth are measured in a direction substantially orthogonal to the surface of the piezoelectric layer.
